(19) United States
(12) Patent Application Publication
(10) Pub. No.: US 2026/0047324 A1
(43) Pub. Date: Feb. 12, 2026

(54) DISPLAY MODULE

(71) Applicant: Samsung Electronics Co., Ltd., Suwon-si (KR)

(72) Inventors: Sounguk Kim, Suwon-si (KR); YUN SEOK CHOI, Suwon-si (KR); Yongmin Yoo, Suwon-si (KR); Insik Han, Suwon-si (KR); JIKHO SONG, Suwon-si (KR); INHO CHOI, Suwon-si (KR)

(21) Appl. No.: 19/028,041

(22) Filed: Jan. 17, 2025

(30) Foreign Application Priority Data
Aug. 7, 2024 (KR) 10-2024-0105206

(51) Int. Cl. H10K 59/80

(52) U.S. Cl. CPC H10K 59/8794; H10K 59/8722; H10K 59/879

(57) ABSTRACT

A display module may include a heat sink having an accommodation recess, a display disposed within the accommodation recess, a cover glass disposed on the heat sink and vertically overlapping at least a portion of the display, and a substrate extending from the accommodation recess to an outside of the heat sink, and having at least a portion disposed on the display to be electrically connected to the display.

### CROSS-REFERENCE TO RELATED APPLICATION

This application claims priority to and the benefit of Korean Patent Application No. 10-2024-0105206 filed in the Korean Intellectual Property Office on Aug. 7, 2024, the entire contents of which are incorporated herein by reference.

### BACKGROUND OF THE INVENTION

### (a) Field of the Invention

The present disclosure relates to a display module.

### (b) Description of the Related Art

Recently, head-mounted display (HMD) devices utilizing ultra-small micro display technology are being developed. Head-mounted display devices can be easily worn by users in the form of glasses or the like, and can provide users with augmented reality (AR) or virtual reality (VR).

Micro displays can be manufactured by using silicon substrates and can achieve high resolution, high brightness, and high reliability. Known types of these micro displays include LED on Silicon (LEDoS) displays that utilize LEDs, OLED on Silicon (OLEDoS) displays that utilize OLEDs, and liquid crystal on silicon (LCoS) displays as a type of LCD series that utilizes liquid crystals.

### SUMMARY OF THE INVENTION

Aspects of the present disclosure provide a display module having excellent heat dissipation characteristics.

Aspects of the present disclosure provide a display module capable of blocking foreign substances from being attached on a lens.

A display module may include a heat sink having an accommodation recess, a display disposed within the accommodation recess, a cover glass disposed on the heat sink and vertically overlapping at least a portion of the display, and a substrate extending from the accommodation recess to an outside of the heat sink, at least a portion of which is disposed on the display to be electrically connected to the display.

A display module may include a heat sink having an accommodation recess, a display including a backplane disposed within the accommodation recess and including a semiconductor substrate, and a frontplane disposed on the backplane and including an LED chip and a lens disposed on the LED chip, a cover glass disposed on the heat sink and vertically overlapping at least a portion of the display, and a substrate extending from the accommodation recess to an outside of the heat sink, at least a portion of which is disposed on the backplane to be electrically connected to the backplane.

A display module may include a heat sink having an accommodation recess, a display a backplane disposed within the accommodation recess and including a semiconductor substrate, and a frontplane disposed on the backplane and including an organic light-emitting layer and a lens disposed on the organic light-emitting layer, a cover glass disposed on the heat sink and covering at least a portion of the display, and a substrate extending from the accommodation recess to an outside of the heat sink and electrically connected to the backplane.

According to one aspect of the present disclosure, a display module having excellent heat dissipation characteristics may be provided.

According to another aspect of the present disclosure, a display module capable of blocking foreign substances from being attached on a lens may be provided.

### BRIEF DESCRIPTION OF THE DRAWINGS

FIG. 1 is a cross-sectional view of a display module according to an embodiment.

FIG. 2 is a perspective view of the display module shown in FIG. 1.

FIG. 3 is a top plan view of the display module shown in FIG. 1.

FIG. 4 shows detailed layers of a heat dissipation layer according to an embodiment.

FIG. 5 is a cross-sectional view of a display module of according to a modified embodiment.

FIG. 6 is a cross-sectional view of a display module according to a modified embodiment.

FIG. 7 is a cross-sectional view of a display that may be included in a display module according to an embodiment.

FIG. 8 is a cross-sectional view of another display that may be included in a display module according to an embodiment.

FIG. 9 is a cross-sectional view of a still another display that may be included in a display module according to an embodiment.

FIG. 10 is a cross-sectional view of a display module according to Comparative Example.

FIG. 11 shows maximum temperatures of display modules according to example embodiments (Examples) and a comparative example (Comparative Example).

### DETAILED DESCRIPTION OF THE EMBODIMENTS

The present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. For better understanding and ease of description, the thicknesses of some layers and areas are exaggerated.

Throughout this specification and the claims that follow, when it is described that an element is “coupled/connected” to another element, the element may be “directly coupled/connected” to the other element or “indirectly coupled/connected” to the other element through a third element. In a similar sense, this includes being “physically connected”as well as being “electrically connected”.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

As used herein, components described as being “electrically connected” are configured such that an electrical signal can be transferred from one component to the other (although such electrical signal may be attenuated in strength as it is transferred and may be selectively transferred).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

In addition, throughout the specification, ordinal numbers such as first and second are used to distinguish a certain component from another component that is the same or similar to the certain component, and are not necessarily intended to refer to a specific component. Accordingly, a component referred to as a first component in a particular portion of the specification may be referred to as a second component in another portion of the specification.

In addition, throughout the specification, a singular reference to a component includes references to a plurality of these components, unless specifically stated to the contrary.

Hereinafter, a display module according to embodiments of the present disclosure will be described with reference to the drawings.

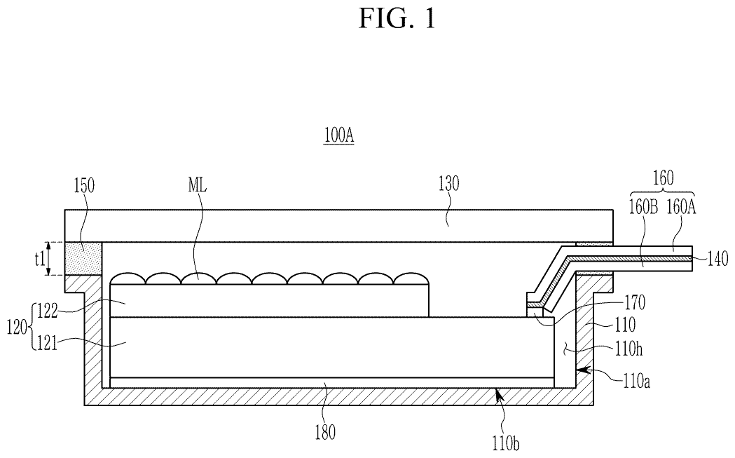

FIG. 1 is a cross-sectional view of the display module according to an embodiment.

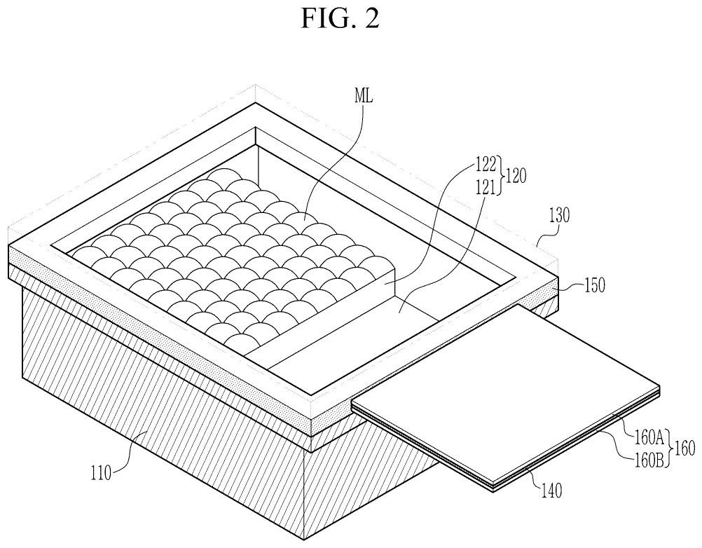

FIG. 2 is a perspective view of the display module shown in FIG. 1.

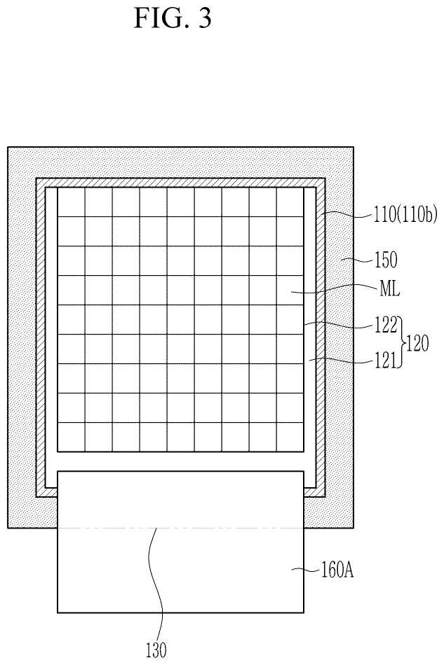

FIG. 3 is a top plan view of the display module shown in FIG. 1.

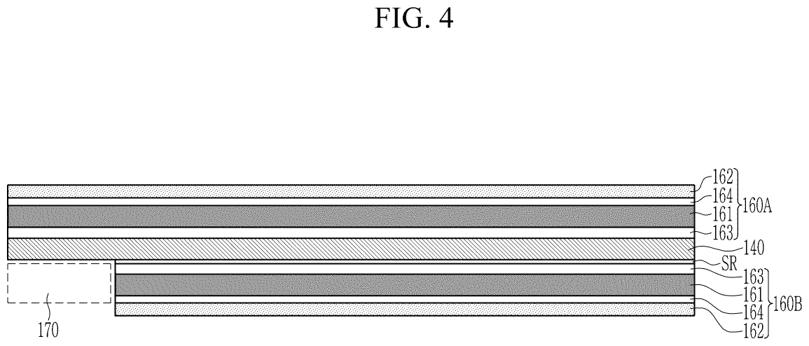

FIG. 4 shows detailed layers of a heat dissipation layer according to an embodiment.

Referring to FIG. 1 to FIG. 3, a display module 100A may include a heat dissipation structure 110 having an accommodation recess 110h, a display 120 disposed within the accommodation recess 110h, a cover glass 130 disposed on the heat dissipation structure 110 and covering (e.g., vertically overlapping) at least a portion of the display 120, and a substrate 140 extending from the accommodation recess 110h to an outer side of the heat dissipation structure 110 and electrically connected to the display 120.

The display module 100A may be applied to, e.g., an AR glasses (augmented reality glasses) in the form of spectacles, and may be mounted on the frame or the hinge of the AR glasses.

The heat dissipation structure 110 may provide a heat dissipation environment by dispersing the heat generated from the display 120. For example, the heat dissipation structure 110 may be a heat sink, a heat spreader, or a cooler. A thermal interface material for forming a heat dissipation route/pathway may be additionally attached on a lower surface of the heat dissipation structure 110.

The heat dissipation structure 110 may have the accommodation recess 110h for accommodating the display 120, and the accommodation recess 110h may include a wall/side surface 110a and a bottom surface 110b. The display 120 may be disposed on the bottom surface 110b of the accommodation recess 110h, and the wall/side surface 110a of the accommodation recess 110h may surround at least a portion of the display 120.

As a material of the heat dissipation structure 110, a conductive material, for example, a metal such as copper (Cu) and aluminum (Al) may be used.

The weight of the heat dissipation structure 110 may be about 0.15 g. The heat dissipation structure 110 may improve its heat dissipation characteristics, without causing a substantial increase of the weight of the display module 100A.

The display 120 may be disposed in the accommodation recess 110h of the heat dissipation structure 110. The display 120 may be disposed on the bottom surface 110b of the accommodation recess 110h, and may be spaced apart from the wall/side surface 110a of the accommodation recess 110h, e.g., in a horizontal direction. The display 120 may be closed and sealed within a space surrounded by the heat dissipation structure 110, the cover glass 130 and a connection member 150 described later, and accordingly, foreign substances may be prevented from being introduced from the outside into the accommodation recess 110h and attached to a lens ML.

The display 120 may be a micro display including a backplane 121 including a semiconductor substrate and a frontplane 122 disposed on the backplane 121. For example, the display 120 may be an LED on Silicon (LEDoS) display or an OLED on Silicon (OLEDoS) display. However, the type of the display 120 is not limited thereto, and for example, the display 120 may be another type of display such as a liquid crystal on silicon (LCoS) display. The micro display may implement the display 120 that has high resolution and high integration and may be miniaturized by utilizing the semiconductor substrate such as silicon.

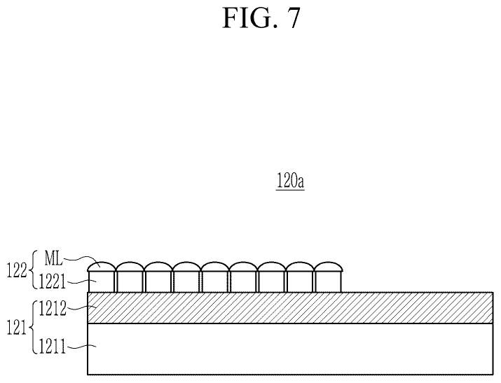

The backplane 121 may enable driving of the display 120 and control respective pixels, and may include a semiconductor substrate 1211 and a circuit structure 1212 disposed on the semiconductor substrate 1211 (see FIG. 7 to FIG. 9). The semiconductor substrate 1211 may include a semiconductor element such as silicon (Si) and germanium (Ge) or a semiconductor compound such as gallium arsenide (GaAs) and indium arsenide (InAs). The circuit structure 1212 may include individual devices, wires, electrodes, or the like, such as transistors, capacitors, and resistors.

The frontplane 122 may include configurations for emitting light, and the detailed configuration may vary depending on the type of the display and its light emitting method. For example, in the case of an LED on Silicon (LEDoS) display, the frontplane 122 may include an LED chip, and in the case of the OLED on Silicon (OLEDoS) display, the frontplane 122 may include an organic light-emitting layer.

The display 120 may include the lens ML disposed uppermost of the display 120. In the present disclosure, the lens ML may be described as a configuration/component included in the frontplane 122. The lens ML may improve the light efficiency and control light distribution, thereby implementing high resolution and high brightness of the display 120. The lens ML may be a micro lens having a small size, and may have a size similar to a pixel of the display 120, e.g., in a plan view. For example, the cross-sectional width (e.g., a width in a horizontal direction) of the lens ML may be several micrometers to tens of micrometers, and may be 10 μm or less or 20 μm or less.

The display 120 may be disposed within the accommodation recess 110h such that the backplane 121 (e.g., a lower surface of the backplane 121) faces the bottom surface 110b of the accommodation recess 110h. Due to the excellent thermal conductivity of the semiconductor substrate 1211 disposed lowermost of the backplane 121, the heat of the display 120 may be efficiently transferred to the heat dissipation structure 110.

The display module 100A may further include the thermal interface material (TIM) 180 disposed between the bottom surface 110b of the accommodation recess 110h and the display 120. The thermal interface material 180 may form the heat dissipation route/pathway, and thereby may enable efficient heat transfer from the display 120 to the heat dissipation structure 110. The type of the thermal interface material 180 may not be particularly limited, and the thermal interface material 180 may have the form of paste, tape, film, adhesive, or the like. As an example, the thermal interface material 180 may include polymer, metal, and/or semiconductor. The inventors have performed stress tests at a high temperature condition of 250° C. through simulation, and have confirmed that the stress applied to the thermal interface material 180 of the display module 100A is at a low level.

The cover glass 130 may be disposed on the heat dissipation structure 110 and covering (e.g., vertically overlapping) the display 120. A central region of the cover glass 130 may be disposed on (e.g., vertically overlap) the accommodation recess 110h of the heat dissipation structure 110 to cover the display 120, and an edge region surrounding the central region may be connected to the heat dissipation structure 110 through the connection member 150. The central region of the cover glass 130 may be spaced apart from the display 120 by a predetermined distance, such that an empty space is formed and exists therebetween. For example, the empty space may be in a vacuum state or may be filled with a gas or air.

The weight of the cover glass 130 may be about 0.02 g to 0.05 g. The cover glass 130 may block foreign substances from being introduced to the lens ML, without causing a substantial increase of the weight of the display module 100A.

The display module 100A may further include the connection member 150 for attaching the cover glass 130 to the heat dissipation structure 110. The connection member 150 may contact an edge region of the heat dissipation structure 110 and an edge region of the cover glass 130, thereby attaching the edge region of the heat dissipation structure 110 and the edge region of the cover glass 130 to each other, and may provide a space in which the display 120 is closed and sealed, together with the heat dissipation structure 110 and the cover glass 130.

In addition, the connection member 150 may extend between the substrate 140 and the heat dissipation structure 110 and between the substrate 140 and the cover glass 130, and may attach the substrate 140 to the heat dissipation structure 110 and the cover glass 130. The connection member 150 may also extend on a side surface of the substrate 140, and the substrate 140 may have a shape that penetrates the connection member 150 between the heat dissipation structure 110 and the cover glass 130. For example, the connection member 150 may be an adhesive layer and may be formed of an adhesive material.

The connection member 150 may include an epoxy resin. Since the connection member 150 includes an epoxy resin, the connection member 150 may have excellent adhesion, durability, and heat resistance.

A thickness t1 of the connection member 150 may be 20 μm or more and 40 μm or less. When a thickness of the connection member 150 is excessively thin, it may be difficult to secure a sufficient mechanical strength, and to uniformly form the thickness of the connection member 150. In addition, when the thickness of the connection member 150 is excessively thick, an entire thickness and weight of the display module 100A may increase.

The substrate 140 may have at least a portion disposed on the display 120, to be electrically connected to the display 120. For example, a portion of the substrate 140 may vertically overlap the display 120. In an embodiment, at least a portion (e.g., an end portion) of the substrate 140 may be disposed on the backplane 121 of the display 120, and electrically connected to the backplane 121.

The substrate 140 may be electrically connected to an electrical power supply device such as a battery, in order to supply electrical power to the display 120 and the display module 100A. In an embodiment, a region disposed outside the heat dissipation structure 110 of the substrate 140 may be electrically connected to the electrical power supply device. For example, the substrate 140 may include a pad or terminal at a portion vertically not overlapping the heat dissipation structure 110, and the pad or terminal may be electrically connected to a power supply. In addition, the substrate 140 may be temporarily connected to test board when testing (e.g., power supplying of) the display module 100A.

The substrate 140 may be a flexible substrate capable of bending. In order to implement the flexible substrate, polyimide, liquid crystal polymer (LCP), epoxy, or the like, having flexibility may be used as an insulation layer of the substrate 140. The substrate 140 may further include wires, vias, connection pads, or the like, in addition to the insulation layer.

The display module 100A may further include a heat dissipation layer 160 disposed on at least one of an upper surface and a lower surface of the substrate 140. For example, the display module 100A may include a first heat dissipation layer 160A disposed on an upper surface of the substrate 140 and a second heat dissipation layer 160B disposed on the lower surface of the substrate 140. However, depending on embodiments, the heat dissipation layer 160 may be omitted from the display module 100A.

Referring to FIG. 4 in order to secure an arrangement space for an anisotropic conductive film 170 described later, the second heat dissipation layer 160B may have a narrower width than the first heat dissipation layer 160A. For example, a portion of the first heat dissipation layer 160A may not vertically overlap the second heat dissipation layer 160B. In certain embodiments, a solder resist layer SR may be additionally disposed between the substrate 140 and the second heat dissipation layer 160B. FIG. 4 illustrates that the substrate 140 and the heat dissipation layer 160 are in the state before being bent by being connected to display 120.

The heat dissipation layer 160 may include a metal tape 161 disposed on the substrate 140, and may further include a protection film 162 disposed on the metal tape 161, as needed.

The metal tape 161 may disperse and/or transfer the heat generated by the substrate 140 or transferred to the substrate 140, thereby providing the heat dissipation environment/pathways. For example, the metal tape 161 may transfer the heat generated from the substrate 140 to the heat dissipation structure 110 through the heat dissipation layer 160. As a material of the metal tape 161, for example, a metal such as copper (Cu) and aluminum (Al) may be used. Depending on embodiments, another material having excellent thermal conductivity to replace the metal tape 161 may be disposed on the substrate 140.

The metal tape 161 may be attached to the substrate 140 through a first adhesive member 163 disposed between the substrate 140 and the metal tape 161. As material of the first adhesive member 163, an epoxy-based adhesive, adhesion film, or the like may be used.

The protection film 162 may protect the metal tape 161 mechanically and chemically. As a material of the protection film 162, a material having an insulating property such as polyimide may be used.

The protection film 162 may be attached to the metal tape 161 through a second adhesive member 164 disposed between the metal tape 161 and the protection film 162. As a material of the second adhesive member 164, an epoxy-based adhesive, adhesion film, or the like may also be used.

Referring back to FIG. 1, the display module 100A may further include the anisotropic conductive film 170 disposed between the display 120 and the substrate 140. The anisotropic conductive film 170 may perform the function to physically attach and electrically connect the display 120 and the substrate 140 to each other. In an embodiment, the anisotropic conductive film 170 may be disposed between the backplane 121 of the display 120 and the substrate 140.

As products such as AR glasses become more multifunctional and perform better, the power consumption of the micro displays applied to them is gradually increasing. In addition, due to foreign substances attached to the lens of the display, the quality of the display module 100A may be deteriorated. According to the present disclosure, heat dissipation characteristics of the display module 100A may be improved by employing the heat dissipation structure 110 connected to the display 120, and the foreign substances may be prevented from being attached to the lens ML by disposing the cover glass 130 on the heat dissipation structure 110.

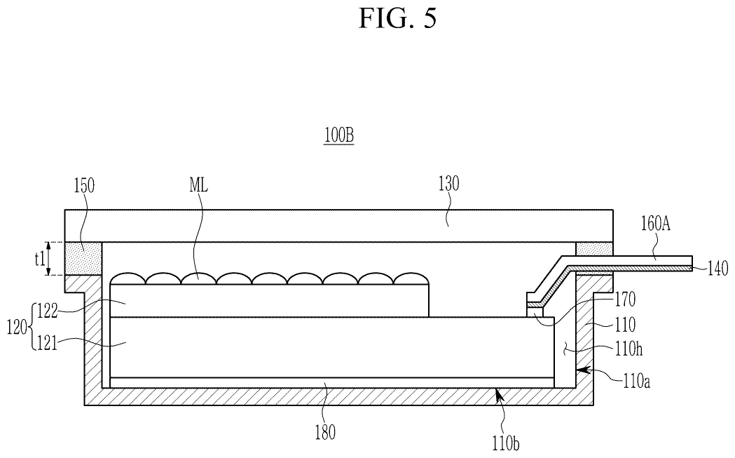

FIG. 5 is a cross-sectional view of the display module according to a modified embodiment.

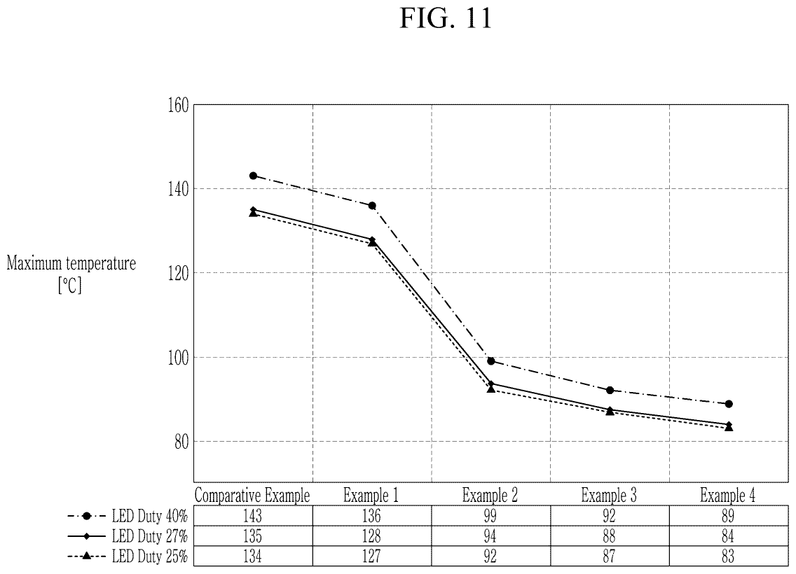

A display module 100B may only include the first heat dissipation layer 160A disposed on the upper surface of the substrate 140, and may not include the second heat dissipation layer 160B disposed on the lower surface of the substrate 140. As will be described later, even if only the first heat dissipation layer 160A is employed, a display module with substantially improved heat dissipation characteristics may be provided as shown in FIG. 11.

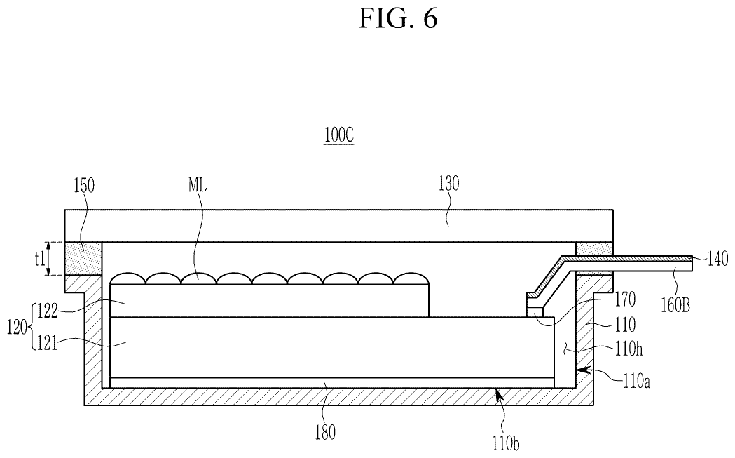

FIG. 6 is a cross-sectional view of a display module according to a modified embodiment.

A display module 100C may only include the second heat dissipation layer 160B disposed on the lower surface of the substrate 140, without including the first heat dissipation layer 160A disposed on the upper surface of the substrate 140. As will be described later, even if only the second heat dissipation layer 160B is employed, a display module with substantially improved heat dissipation characteristics may be provided as shown in FIG. 11.

FIG. 7 is a cross-sectional view of a display that may be included in the display module according to an embodiment.

A display 120a may be an LED on Silicon (LEDoS) display including a backplane 121 and a frontplane 122 disposed on the backplane 121.

The backplane 121 may enable driving of the display 120a and control respective pixels, and may include a semiconductor substrate 1211 and a circuit structure 1212 disposed on the semiconductor substrate 1211. The semiconductor substrate 1211 may include a semiconductor element such as silicon (Si) and germanium (Ge) or a semiconductor compound such as gallium arsenide (GaAs) and indium arsenide (InAs). The circuit structure 1212 may include individual devices, wires, electrodes, and the like, such as conductive patterns, transistors, capacitors, and resistors.

The frontplane 122 may include an LED chip 1221 and a lens ML disposed on the LED chip 1221. A plurality of LED chips 1221 may be arranged in a matrix form to implement a display of high resolution. The LED chips 1221 may emit light of one of R (red), G (green), and B (blue) colors, respectively, and a single LED chip 1221 may emit lights of all three colors of R, G, and B. Alternatively, the LED chip 1221 may emit the light of white color, and in such a case, color filters may be additionally disposed in order to implement colors. The LED chip 1221 may be protected by being covered by a molding material. The lens ML may improve the light efficiency and control light distribution, thereby, implementing high resolution and high brightness of the display 120a.

In addition, the display 120a may further include known configurations included in LED on Silicon (LEDoS) displays.

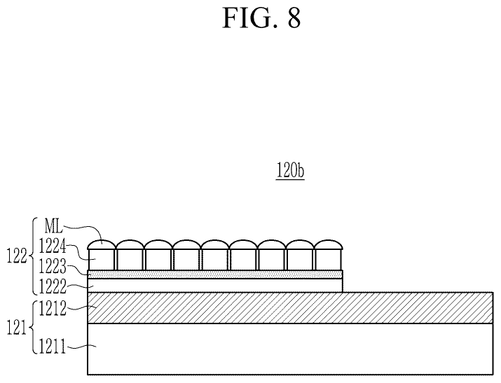

FIG. 8 is a cross-sectional view of a display according to another embodiment.

A display 120b may be an OLED on Silicon (OLEDoS) display including a backplane 121 and a frontplane 122 disposed on the backplane 121, and for example, may be a white OLED display utilizing color filters.

The backplane 121 may enable driving of the display 120b and control respective cells, and may include a semiconductor substrate 1211 and a circuit structure 1212 disposed on the semiconductor substrate 1211. The semiconductor substrate 1211 may include a semiconductor element such as silicon (Si) and germanium (Ge) or a semiconductor compound such as gallium arsenide (GaAs) and indium arsenide (InAs). The circuit structure 1212 may include individual devices, wires, electrodes, and the like, such as conductive patterns, transistors, capacitors, and resistors.

The frontplane 122 may include an organic light-emitting layer 1222, a lens ML disposed on the organic light-emitting layer 1222, and a color filter 1224 disposed between the organic light-emitting layer 1222 and the lens ML. In the white color OLED, the organic light-emitting layer 1222 may include the white light emitting layer and may emit the white light. A molding material 1223 for protecting the organic light-emitting layer 1222 may exist on the organic light-emitting layer 1222 of the frontplane 122. The color filters 1224 may include a red color filter, a green color filter and a blue color filter, and may implement a desired color by filtering the white light emitted from the organic light-emitting layer 1222 of each pixel. The lens ML may improve the light efficiency and control light distribution, thereby implementing high resolution and high brightness of the display 120b.

In addition, the display 120b may further include known configurations included in OLED on Silicon (OLEDoS) displays utilizing the white color OLED.

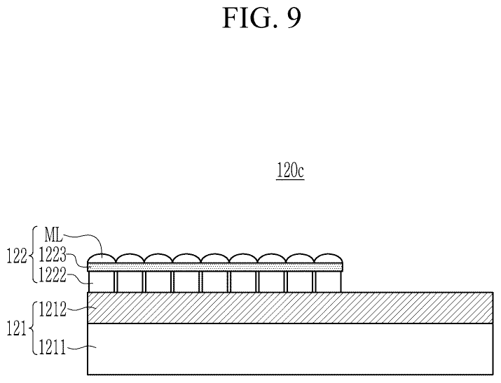

FIG. 9 is a cross-sectional view of the display according to another embodiment.

A display 120c may be an OLED on Silicon (OLEDoS) display including a backplane 121 and a frontplane 122 disposed on the backplane 121, and for example, may be an RGB-type OLED display.

The backplane 121 may enable driving of the display 120c and control respective cells, and may include a semiconductor substrate 1211 and a circuit structure 1212 disposed on the semiconductor substrate 1211. The semiconductor substrate 1211 may include a semiconductor element such as silicon (Si) and germanium (Ge) or a semiconductor compound such as gallium arsenide (GaAs) and indium arsenide (InAs). The circuit structure 1212 may include individual devices, wires, electrodes, and the like, such as conductive patterns, transistors, capacitors, and resistors.

The frontplane 122 may include an organic light-emitting layer 1222 and a lens ML disposed on the organic light-emitting layer 1222. In the RGB-type OLED display, the organic light-emitting layer 1222 may emit red, green, and blue lights, and accordingly, color filters may not be additionally required. Light-emitting materials emitting red, green, and blue lights may be disposed side by side within each pixel. A molding material 1223 for protecting the organic light-emitting layer 1222 may exist on the organic light-emitting layer 1222 of the frontplane 122. The lens ML may improve the light efficiency and control light distribution, thereby implementing high resolution and high brightness of the display 120c.

In addition, the display 120c may further include known configurations included in OLED on Silicon (OLEDoS) displays of the RGB type.

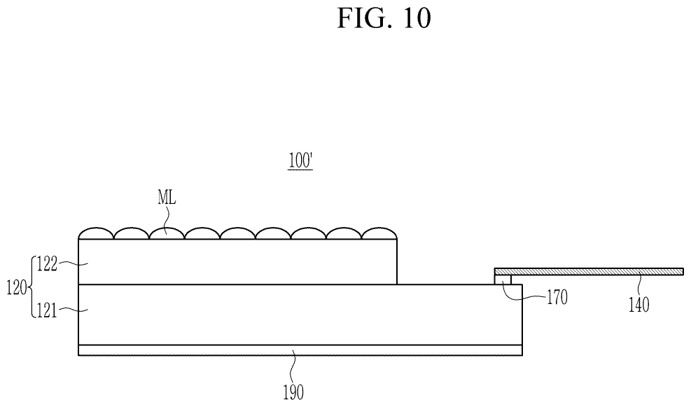

FIG. 10 is a cross-sectional view of the display module according to a comparative example (Comparative Example).

A display module 100′ according to the Comparative Example may include a display 120 and a substrate 140 electrically connected to the display 120, and may not include a heat dissipation structure 110, a cover glass 130 and a heat dissipation layer 160.

Since the display module 100′ does not include a cover glass 130, foreign substances may not be prevented from being introduced from the outside and may be attached to a lens ML placed at the top of the display 120. In addition, the display module 100′ has a low heat dissipation efficiency by not including a heat dissipation structure 110 and a heat dissipation layer 160.

Hereinafter, the heat dissipation characteristics of the display module according to the example embodiments and the Comparative Example will be discussed through simulation results.

FIG. 11 shows maximum temperatures of the display modules according to example embodiments (Examples 1 through 4) and the Comparative Example.

Example 1 is a display module in which the heat dissipation layer 160 disposed on both surfaces of the substrate 140 is omitted from the display module 100A of FIG. 1. Example 2 is the display module 100B of FIG. 5 including the first heat dissipation layer 160A and not including a second heat dissipation layer 160B on the lower surface of the substrate 140. Example 3 is the display module 100C of FIG. 6 including the second heat dissipation layer 160B and not including a first heat dissipation layer 160A on the upper surface of the substrate 140. Example 4 is the display module 100A of FIG. 1 including both of the first heat dissipation layer 160A and the second heat dissipation layer 160B. In addition, the LEDoS display 120a shown in FIG. 7 was used in the display modules of the Comparative Example and the embodiments.

Referring to the simulation results, when the LED duty was set to 25% to 40% (blue LED duty: 40%, green LED duty: 27%, red LED duty: 25%), the maximum temperatures of the LED chips in Comparative Example, Example 1, Example 2, Example 3, and Example 4 were measured or resulted to be 143° C., 136° C., 99° C., 92° C., and 89° C., respectively. That is, the maximum temperatures of the LED chips in Example 1, Example 2, Example 3, and Example 4 are decreased from or lower than those of Comparative Example by 5%, 44%, 55%, and 61%. That is, according to the present disclosure, a display module having excellent heat dissipation characteristics may be provided.

While this disclosure has been described in connection with embodiments, it is to be understood that the disclosure is not limited to the disclosed embodiments, but, is intended to cover various modifications and equivalent arrangements as the invention is defined by the scope of the appended claims.

Additionally, the embodiments of the present disclosure are not exclusive of each other and may be implemented in combination with each other unless there is a particular conflict. Accordingly, additional embodiments in which components/elements of embodiments of the present disclosure are combined with each other partly or wholly should also be considered to be included in the present disclosure.

What is claimed is:

1. A display module, comprising:
a heat sink having an accommodation recess;
a display disposed within the accommodation recess;
a cover glass disposed on the heat sink and vertically overlapping at least a portion of the display; and
a substrate extending from the accommodation recess to an outside of the heat sink, at least a portion of which is disposed on the display to be electrically connected to the display.

2. The display module of claim 1, further comprising an adhesive layer disposed between the heat sink and the cover glass.

3. The display module of claim 2, wherein the adhesive layer extends between the substrate and the heat sink and between the substrate and the cover glass.

4. The display module of claim 2, wherein the adhesive layer is in contact with an edge region of the heat sink and an edge region of the cover glass.

5. The display module of claim 2, wherein the adhesive layer comprises an epoxy resin.

6. The display module of claim 1, further comprising a heat dissipation layer disposed on at least one of an upper surface and a lower surface of the substrate, and comprising a metal tape.

7. The display module of claim 6, wherein the heat dissipation layer further comprises a protection film disposed on the metal tape.

8. The display module of claim 1, further comprising an anisotropic conductive film disposed between the display and the substrate.

9. The display module of claim 1, wherein the display comprises a lens disposed at an uppermost portion of the display.

10. The display module of claim 1, further comprising a thermal interface material disposed between a bottom surface of the accommodation recess and the display.

11. The display module of claim 1, wherein the display is spaced apart from a wall surface of the accommodation recess.

12. The display module of claim 1, wherein the display comprises a semiconductor substrate.

13. A display module, comprising:
a heat sink having an accommodation recess;
a display disposed within the accommodation recess and comprising a semiconductor substrate comprising a backplane, and a frontplane disposed on the backplane and comprising an LED chip and a lens disposed on the LED chip;
a cover glass disposed on the heat sink and vertically overlapping at least a portion of the display; and
a substrate extending from the accommodation recess to an outside of the heat sink and electrically connected to the backplane.

14. The display module of claim 13, further comprising an adhesive layer disposed between the heat sink and the cover glass.

15. The display module of claim 13, further comprising a heat dissipation layer disposed on at least one of an upper surface and a lower surface of the substrate, and comprising a metal tape.

16. A display module, comprising:
a heat sink having an accommodation recess;
a display disposed within the accommodation recess and comprising a semiconductor substrate comprising a backplane, and a frontplane disposed on the backplane and comprising an organic light-emitting layer and a lens disposed on the organic light-emitting layer;
a cover glass disposed on the heat sink and covering at least a portion of the display; and
a substrate extending from the accommodation recess to an outside of the heat sink and electrically connected to the backplane.

17. The display module of claim 16, wherein:
the organic light-emitting layer is configured to emit a white light; and
the frontplane further comprises a color filter disposed between the organic light-emitting layer and the lens.

18. The display module of claim 16, wherein the organic light-emitting layer is configured to emit red, green, and blue lights.

19. The display module of claim 16, further comprising an adhesive layer disposed between the heat sink and the cover glass.

20. The display module of claim 16, further comprising a heat dissipation layer disposed on at least one of an upper surface and a lower surface of the substrate, and comprising a metal tape.
